(19) United States
(12) Patent Application Publication
(10) Pub. No.: US 2013/0119530 A1
(43) Pub. Date: May 16, 2013

(54) THERMALLY ENHANCED PACKAGING STRUCTURE

(71) Applicants: AN HONG LIU, Hsinchu (TW); David Wei Wang, Hsinchu (TW); Shi Fen Huang, Hsinchu (TW); Yi Chang Lee, Hsinchu (TW); Hsiang Ming Huang, Hsinchu (TW)

(72) Inventors: AN HONG LIU, Hsinchu (TW); David Wei Wang, Hsinchu (TW); Shi Fen Huang, Hsinchu (TW); Yi Chang Lee, Hsinchu (TW); Hsiang Ming Huang, Hsinchu (TW)

(73) Assignee: CHIPMOS TECHNOLOGIES INC., HSINCHU (TW)

(21) Appl. No.: 13/588,363

(22) Filed: Aug. 17, 2012

(30) Foreign Application Priority Data
Nov. 11, 2011 (TW) 100141214

(51) Int. Cl. H01L 23/34

(52) U.S. Cl. 257/706; 257/E23.08

(57) ABSTRACT

A thermally enhanced packaging structure includes a chip carrier; a high power chip disposed on the chip carrier; a molding compound covering the high power chip; a heat dissipating layer disposed on the molding compound, wherein the heat dissipating layer comprises a plurality of carbon nanocapsules (CNCs); and a non-fin type heat dissipating device, disposed either on the heat dissipating layer or between the molding compound and the heat dissipating layer. The molding compound can also comprise a plurality of CNCs.

### BACKGROUND OF THE INVENTION

1. Technical Field

The present invention relates to a thermally enhanced packaging structure, and more particularly, to a thermally enhanced packaging structure having a non-fin type, heat dissipation device and a plurality of carbon nanocapsules (CNCs).

2. Background

Current trends of the semiconductor device manufacturing industry include the decrease in the scale of devices and increases in data processing speed, resulting in a circuit layout of high device density and therefore, a greater heat generation per unit area. As portable consumer electronics products such as cellular phones and tablet PCs advance rapidly, the scale of the heat dissipation packing structure should be deliberately designed to fit inside hand-held electronic products. A heat dissipation structure that does not occupy too much device real estate and that provides efficient heat distribution is required to keep up with the rapid pace of advancements in the manufacturing of portable electronic products.

Conventional packaging structures have two different forms: FIG. 1 shows a heat dissipation packaging structure 10 disposed on a packaged semiconductor chip (not shown), the structure 10 comprising: a chip carrier 11; a high power chip 14 positioned on the chip carrier 11; a molding compound 13 encapsulating the high power chip 14; and a fin type heat dissipation device 15 disposed on the molding compound 13. The structure 10 further comprises a plurality of solder balls 17 positioned on a surface opposite to the high power chip 14 of the chip carrier 11. FIG. 2 shows a conventional heat dissipation packaging structure 20, the structure 20 including: a chip carrier 21; a high power chip 24 positioned on the chip carrier 21; a molding compound 23 encapsulating the high power chip 24; and a planar heat dissipation device 25 disposed on the molding compound 23. The structure 20 further comprises a plurality of solder balls 27 positioned on a surface opposite to the high power chip 24 of the chip carrier 21.

The structures shown in FIGS. 1 and 2 are both considered thick and large, and therefore are not ideal candidates for application in portable electronic products. Conventional heat dissipation packaging structure such as those shown in FIGS. 1 and 2 has heat dissipating capability proportional to the surface area in contact with the ambient environment. As can be seen in FIG. 1, a greater number of fins corresponds to better heat dissipating efficiency; however, this structure incurs a higher cost and a greater effective thickness. In contrast, a planar heat dissipation packaging structure has a lower cost and thinner structural geometry, but at the expense of lower heat dissipation efficiency. In order to meet the stringent requirements of advancing technology, the conventional structure further enhances the heat dissipation efficiency by implementing forced convection, that is, by adding a fan proximal to the heat dissipation packaging structure.

Therefore, a heat dissipation structure that does not occupy excessive device real estate and that is efficient at heat distribution is required to keep pace with the manufacturing trend of electronic products having thinner geometry and greater heat generation per unit area.

### SUMMARY

One embodiment of the present disclosure provides a thermally enhanced packaging structure, and the structure includes a chip carrier; a high power chip positioned on the chip carrier; a molding compound encapsulating the high power chip; a heat dissipation layer positioned on the molding compound, wherein the heat dissipation layer comprises a plurality of carbon nanocapsules (CNCs); and a non-fin type, heat-dissipation device is coupled with the heat dissipation layer.

Another embodiment of the present disclosure provides another thermally enhanced packaging structure, and the structure includes a chip carrier; a high power chip positioned on the chip carrier; a molding compound encapsulating the high power chip, wherein a plurality of carbon nanocapsules (CNCs) are blended in the molding compound; and a non-fin type, heat-dissipation device, positioned on the molding compound.

The foregoing as outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 illustrates a conventional heat dissipation packaging structure;

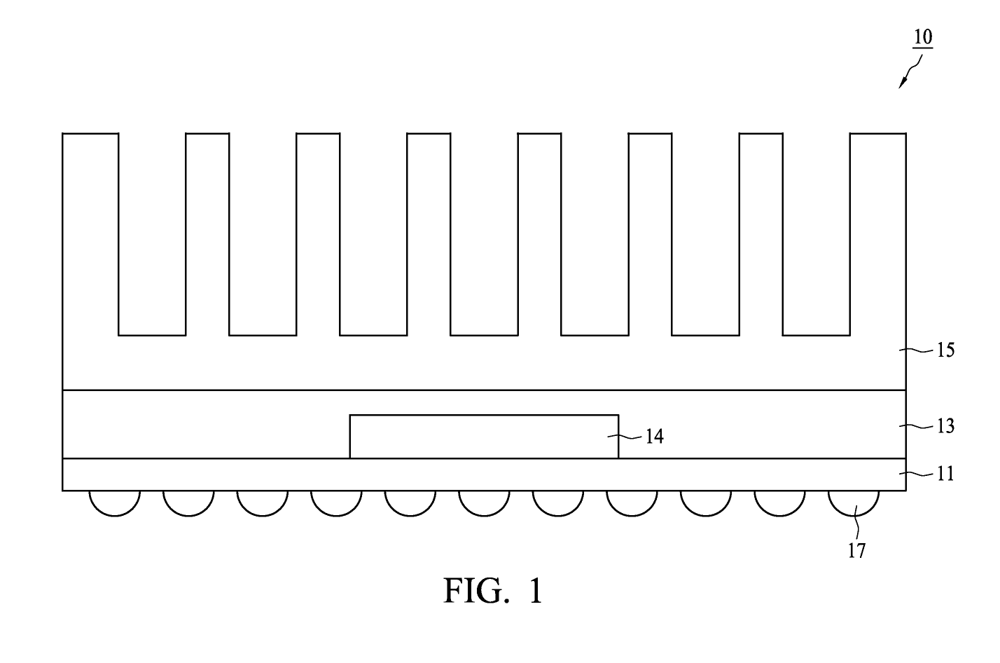

FIG. 2 illustrates a conventional heat dissipation packaging structure;

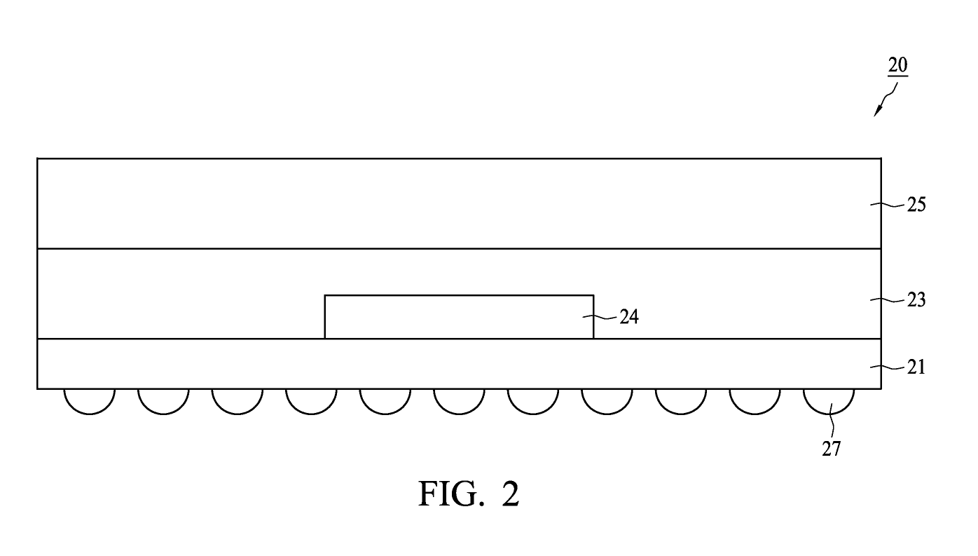

FIG. 3 illustrates a thermally enhanced packaging structure according to an embodiment of the present disclosure;

FIG. 4 illustrates a thermally enhanced packaging structure according to another embodiment of the present disclosure; and

FIG. 5 illustrates a thermally enhanced packaging structure according to yet another embodiment of the present disclosure.

### DETAILED DESCRIPTION

Carbon nanocapsule (CNC) is a crystalline form of carbon atoms, having a dimension of between 1 and 100 nm, most typically 30 nm. CNCs possess a special physical property to efficiently absorb the heat generated by semiconductor devices, under high temperature; and to release the absorbed energy through the form of infrared (IR). Normally a silicon substrate has an energy gap of 1.1 eV, and therefore is transparent to IR and does not absorb any heat released by CNCs. Integrating CNCs into a silicon-based packaging structure therefore can raise the effect of heat dissipation efficiently. In addition, due to the implementation of CNCs, the thickness of the packaging structure can be decreased. The present disclosure provides the following embodiments which include CNCs in the thermally enhanced packaging structure.

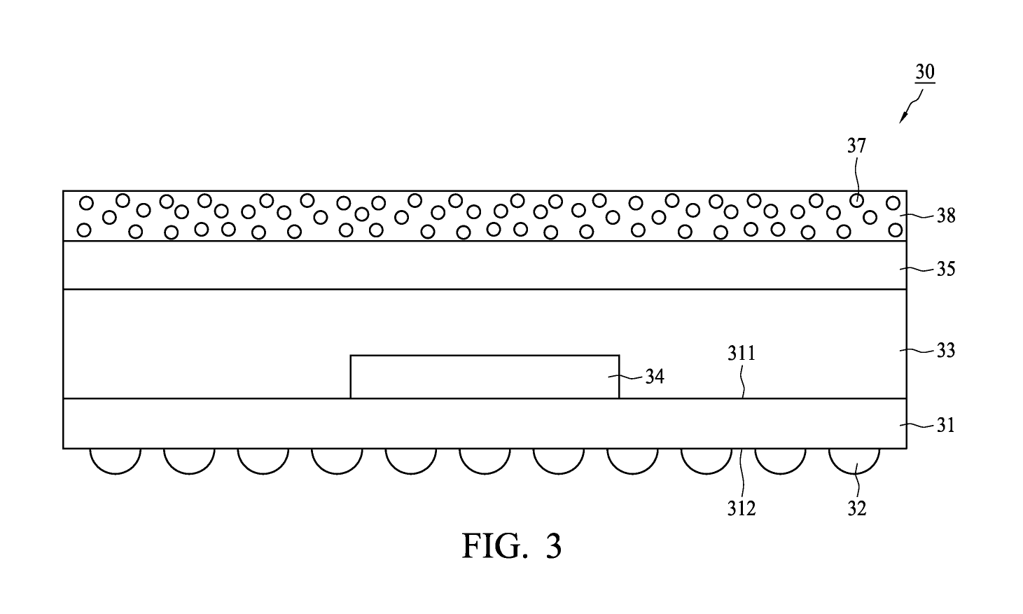

FIG. 3 is a thermally enhanced packaging structure 30 according to one embodiment of the present disclosure, the structure including: a chip carrier 31; a high power chip 34 positioned on the chip carrier 31; a plurality of solder balls 32 disposed on a lower surface 312 opposite to the high power chip of the chip carrier 31; a molding compound 33 encapsulating the high power chip 34 and positioned on an upper surface 311 of the chip carrier 31; a heat dissipation layer 38 positioned on the molding compound 33, wherein the heat dissipation layer comprises a plurality of carbon nanocapsules (CNCs) 37; and a non-fin type, heat-dissipation device 35, positioned between the molding compound 33 and the heat dissipation layer 38. The chip carrier 31 can be, but is not limited to, a flexible substrate, a rigid substrate, or a semiconductor substrate, typically a silicon substrate. The high power chip 34 is positioned on an upper surface 311 of the chip carrier 31. In general, the high power chip 34 is allowed to have an output power of more than 0.5 W, and the electrical connection between the chip 34 and the carrier 31 can be through metal bumps or metal wire (omitted in the drawing). The current high power light emitting devices or central processing units are suitable for this packaging structure. The molding compound 33 used in the present embodiment can be, but is not limited to, epoxy or thermally enhanced epoxy with heat conducting fillers.

The form of the heat dissipation layer 38 includes, but is not limited to, thin film, paste, and powder coating. The above-mentioned materials are configured to include a plurality of CNCs 37. Due to their excellent heat dissipating nature, CNCs can effectively dissipate heat even if only 1 wt % of the CNC is blended in the heat dissipation layer 38. The formation method of the heat dissipation layer 38 includes, but is not limited to, dispensing, screen printing, stencil printing, spin coating, spraying, stamping, sputtering, evaporation, dipping, plating, and plasma-enhanced chemical vapor deposition. In addition, the surface of the CNCs can be functionalized in facilitating the adhesion between the heat dissipation layer 38 and the heat dissipation device without any additional step or adhesives. The unit composed of the heat dissipation layer 38 and the heat dissipation device 35 can be directly combined with the conventional packaging manufacturing process and can be implemented on all kinds of semiconductor packaging structures.

The heat dissipation device 35 can be a non-fin type heat dissipation layer, for example, a planar heat dissipation layer. The heat dissipation layer can be a metal foil selected from the group of copper and aluminum. The conventional fin-type heat dissipation layer is higher in cost and thicker in profile, and therefore does not meet the thin and light requirements of current portable electronic products. The implementation of the CNCs can effectively decrease the thickness of the heat dissipation layer and increase the heat dissipation efficiency.

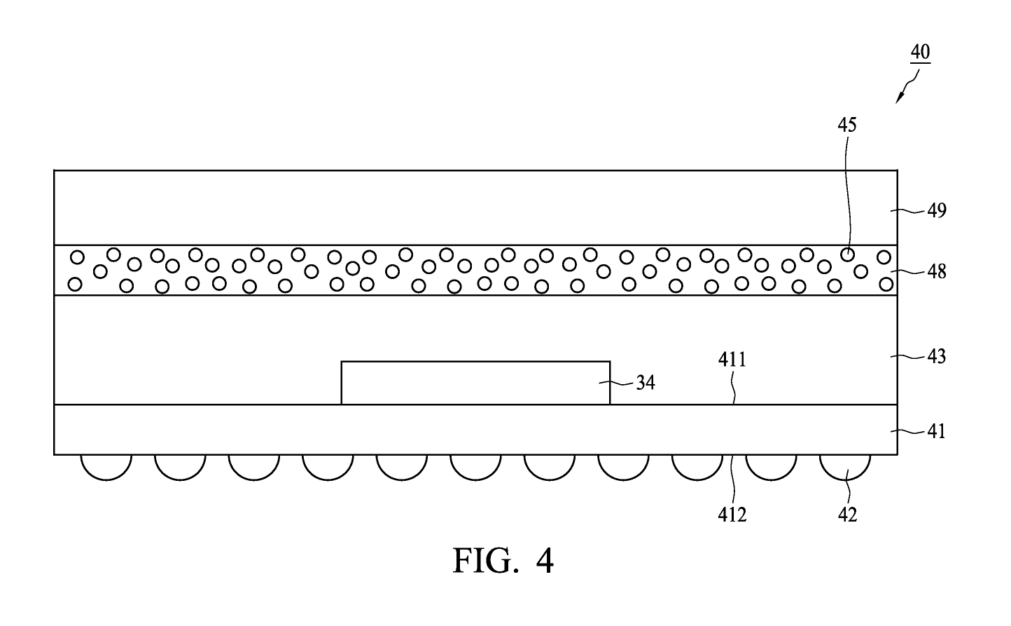

FIG. 4 is a thermally enhanced packaging structure 40 according to one embodiment of the present disclosure, the structure 40 including: a chip carrier 41; a high power chip 34 positioned on the chip carrier 41; a plurality of solder balls 42 disposed on a lower surface 412 opposite to the high power chip of the chip carrier 41; a molding compound 43 encapsulating the high power chip 34 and positioned on an upper surface 411 of the chip carrier 41; a heat dissipation layer 48 positioned on the molding compound 43, wherein the heat dissipation layer 48 comprises a plurality of CNCs 45; and a non-fin type heat-dissipation device 49, positioned on the heat dissipation layer 48. The chip carrier 41 can be, but is not limited to, a flexible substrate, a rigid substrate, or a semiconductor substrate, typically a silicon substrate. The high power chip 34 is positioned on an upper surface 411 of the chip carrier 41. In general, the high power chip 34 can have an output power of more than 0.5 W, and the electrical connection between the chip 34 and the carrier 41 can be through metal bumps or metal wire (omitted in the drawing). The current high power light emitting devices or central processing units are suitable for this packaging structure. The molding compound 43 used in the present embodiment can be, but is not limited to, epoxy, or thermally enhanced epoxy with heat conducting fillers.

The form of the heat dissipation layer 48 includes, but is not limited to, thin film, paste, and powder coating. The above-mentioned materials are configured to include a plurality of CNCs 45. Due to their excellent heat dissipating nature, CNCs can effectively dissipate the heat even if only 1 wt % of the CNCs are blended in the heat dissipation layer 48. The formation method of the heat dissipation layer 48 includes, but is not limited to, dispensing, screen printing, stencil printing, spin coating, spraying, stamping, sputtering, evaporation, dipping, plating, and plasma-enhanced chemical vapor deposition. In addition, the surface of the CNCs can be functionalized to facilitate the adhesion between the heat dissipation layer 48 and the heat dissipation device 49, without any additional step or additional adhesives. The unit composed of the heat dissipation layer 48 and the heat dissipation device 49 can be directly combined with the conventional packaging manufacturing process and can be implemented on all kinds of semiconductor packaging structures.

The heat dissipation device 49 can be a non-fin type heat dissipation layer, for example, a planar heat dissipation layer. The heat dissipation layer can be a metal foil selected from the group of copper and aluminum. The conventional fin-type heat dissipation layer is higher in cost and thicker in profile, therefore does not meet the thin and light requirement of current portable electronic products. The implementation of CNCs can effectively decrease the thickness of the heat dissipation layer and increase the heat dissipation efficiency.

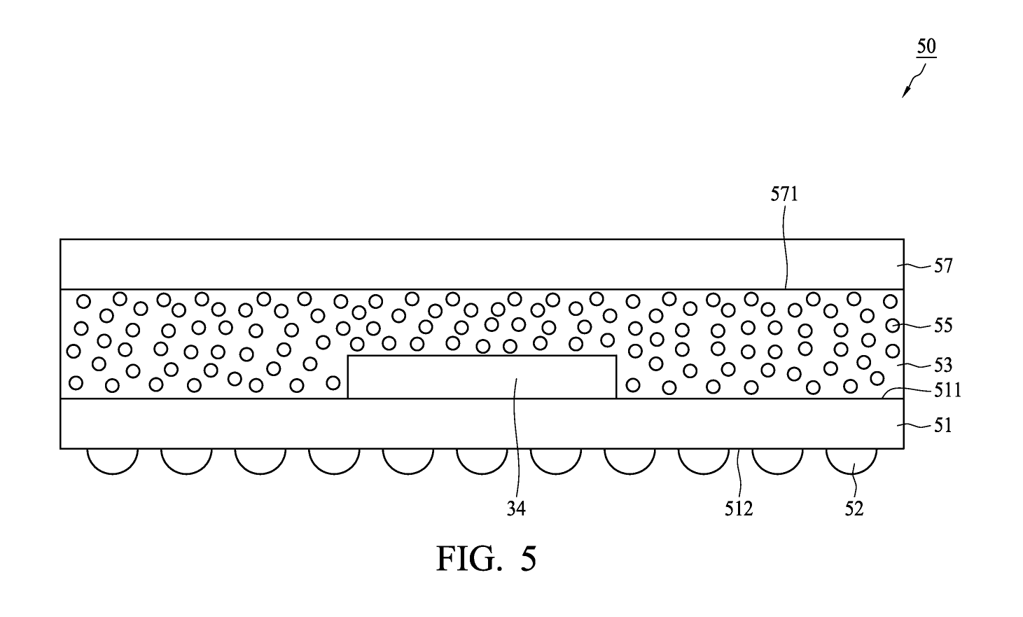

FIG. 5 is a thermally enhanced packaging structure 50 according to one embodiment of the present disclosure, the structure 50 including: a chip carrier 51; a high power chip 34 positioned on the chip carrier 51; a plurality of solder balls 52 disposed on a lower surface 512 opposite to the high power chip of the chip carrier 51; a molding compound 53 encapsulating the high power chip 34 and positioned on an upper surface 511 of the chip carrier 51; and a non-fin type, heat-dissipation device 57, positioned on the molding compound 53, wherein the inside the molding compound 53 includes a blend of a plurality of CNCs 55. In the present embodiment, the chip carrier 51 can be, but is not limited to, a flexible substrate, a rigid substrate, or a semiconductor substrate. The high power chip 34 is positioned on an upper surface 511 of the chip carrier 51. In general, the high power chip 34 can have an output power of more than 0.5 W, and the electrical connection between the chip 34 and the carrier 51 can be through metal bumps or metal wire (omitted in the drawing). The current high power light emitting devices or central processing units are suitable for this packaging structure. The molding compound 53 used in the present embodiment can be, but is not limited to, epoxy, or thermally enhanced epoxy with heat conducting fillers.

The materials of the molding compound 53 include epoxy or thermally enhanced epoxy. Both of the above-mentioned materials are configured to include a plurality of CNCs 55 blended in. Due to their excellent heat dissipating nature, CNCs can effectively dissipate the heat even if only 1 wt % of CNCs are blended in the heat dissipation layer 53. In addition, the surface of the CNCs can be functionalized to facilitate the adhesion to the upper surface 511 of the chip carrier 51 and to the lower surface 571 of the non-fin type, heat dissipation device 57, without any additional step or additional adhesives. The CNCs blended inside the molding compound 53 are configured to be non conductive, allowing the integrity of the insulating property of the molding compound 53 to be retained. The unit composed of the molding compound 53 and the non-fin type, heat dissipation device 57 can be directly combined with the conventional packaging manufacturing process and can be implemented on all kinds of semiconductor packaging structures.

The heat dissipation device 57 can be a non-fin type heat dissipation layer, for example, a planar heat dissipation layer. The heat dissipation layer can be a metal foil selected from the group of copper and aluminum. The conventional fin-type heat dissipation layer is higher in cost and thicker in the profile, and therefore does not meet the thin and light requirement of current portable electronic products. Therefore, the implementation of CNCs can effectively decrease the thickness of the heat dissipation layer and increase the heat dissipation efficiency.

A CNC-containing heat dissipation layer or molding compound can be directly integrated with current packaging structures, such as lead frame based packaging, wafer-level chip scale packaging, substrate based packaging, ceramic based packaging, multi-chip packaging, 3D-IC packaging, system-in-package, subsystem packaging, module packaging, etc. The thermally enhanced packaging structure disclosed in the present invention can solve the problem of poor heat dissipation capability in thin profile heat dissipation packaging structure by implementing CNCs.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A thermally enhanced packaging structure, comprising:
a chip carrier;
a high power chip positioned on the chip carrier;
a molding compound encapsulating the high power chip;
a heat dissipation layer positioned on the molding compound, wherein the heat dissipation layer comprises a plurality of carbon nanocapsules (CNCs); and
a non-fin type, heat-dissipation device, coupled with the heat dissipation layer.

2. The thermally enhanced packaging structure of claim 1, wherein the heat-dissipation device is positioned on the heat dissipation layer.

3. The thermally enhanced packaging structure of claim 1, wherein the heat-dissipation device is positioned between the molding compound and the heat dissipation layer.

4. The thermally enhanced packaging structure of claim 1, wherein the forms of the heat dissipation layer comprise thin films, pastes, or powder coating.

5. The thermally enhanced packaging structure of claim 1, further comprising a plurality of solder balls disposed on the surface opposite to the high power chip of the chip carrier.

6. The thermally enhanced packaging structure of claim 1, wherein the high power chip comprises an output power greater than 0.5 W.

7. The thermally enhanced packaging structure of claim 1, wherein the non-fin type, heat dissipation device comprises a planar geometry.

8. The thermally enhanced packaging structure of claim 7, wherein the planar heat dissipation device is a metal foil comprising a material selected from the group consisting of copper and aluminum.

9. A thermally enhanced packaging structure, comprising:
a chip carrier;
a high power chip positioned on the chip carrier;
a molding compound encapsulating the high power chip, wherein a plurality of carbon nanocapsules (CNCs) are blended in the molding compound; and
a non-fin type heat-dissipation device positioned on the molding compound.

10. The thermally enhanced packaging structure of claim 9, further comprising a plurality of solder balls positioned on the surface opposite to the high power chip of the chip carrier.

11. The thermally enhanced packaging structure of claim 9, wherein the high power chip comprises an output power greater than 0.5 W.

12. The thermally enhanced packaging structure of claim 9, wherein the non-fin type, heat dissipation device comprises a planar geometry and the planar heat dissipation device is a metal foil comprising a material selected from the group consisting of copper and aluminum.
